(19) United States
(12) Patent Application Publication
(10) Pub. No.: US 2026/0333909 A1
(43) Pub. Date: Oct. 22, 2026

(54) COVER AND RECORDING DEVICE UTILIZING SAID COVER

(71) Applicant: NHK SPRING CO., LTD., Yokohama-shi, Kanagawa (JP)

(72) Inventors: Toshimitsu ARAKI, Yokohama-shi, Kanagawa (JP); Osamu OKAWARA, Yokohama-shi, Kanagawa (JP); Mitsuhiro KONDO, Yokohama-shi, Kanagawa (JP); Wataru MIYAZAKI, Yokohama-shi, Kanagawa (JP)

(21) Appl. No.: 19/114,708

(22) PCT Filed: Sep. 22, 2023
(86) PCT No.: PCT/JP2023/034526

§ 371 Date: Mar. 24, 2025

(30) Foreign Application Priority Data
Sep. 30, 2022 (JP) 2022-158917

(51) Int. Cl. H10F 39/00

(52) U.S. Cl. CPC H10F 39/804

(57) ABSTRACT

A cover to be attached to an opening of a base of a housing accommodating an internal mechanism in a space to close the space, is provided with an outer peripheral portion received by the base, and a gasket extending along the outer peripheral portion in a circumferential shape and projecting from the outer peripheral portion to be compressed by contact to the base, wherein the gasket has a large width portion being relatively large in width spanning between an inside and an outside of the circumferential shape and a small width portion being relatively small in the width, and the small width portion is raised by a layer structure having a raising layer in a compression direction of the gasket.

### FIELD OF THE INVENTION

The present invention relates to a cover for a recording device such as a hard disk drive and a recording device using the cover.

### BACKGROUND OF THE INVENTION

A hard disk drive as a recording device accommodates an internal mechanism including disks being recording media in a space and requires sealability so that dust, moisture and the like are not entered into the space.

For such scalability, a gasket is generally provided between a base and a cover of a housing defining a space (Patent literature 1, for example). The gasket is circumferentially provided along an outer periphery of the cover received by the base, and is interposed and compressed between the cover and the base.

In some cases, the gasket has a small width portion in which a width spanning between an inside and an outside of a circumferential shape is partially reduced according to spatial restriction. The small width portion is easily set by variations of discharging conditions such as a discharging amount if a liquid gasket discharged from an application tool such as a needle is applied to the cover to be cured.

A projection height of the small width portion from the cover is, however, dependent on a width of the liquid gasket at the time of discharging to some extent, so that the projection height is smaller than of the other portions of the gasket. As this result, the small width portion may reduce the sealability of the gasket.

PATENT LITERATURE 1: JPH08-045264A

### SUMMARY OF THE INVENTION

A problem to be solved is that there is a risk to reduce a projection height to lower sealability at a small width portion of a gasket.

The present invention provides a cover to be attached to an opening of a base of a housing accommodating an internal mechanism in a space to close the space. The cover is provided with an outer peripheral portion received by the base, and a gasket extending along the outer peripheral portion in a circumferential shape and projecting from the outer peripheral portion to be compressed by contact to the base. The gasket has a large width portion being relatively large in width spanning between an inside and an outside of the circumferential shape and a small width portion being relatively small in the width. The small width portion is raised by a layer structure having a raising layer in a compression direction of the gasket.

Further, the present invention provides a recording device using the aforementioned cover. The recording device is provided with a base forming a housing together with the cover to accommodate an internal mechanism in a closed space. The base is provided with an opening to which the cover is attached, and a cover-receiving portion receiving the outer peripheral portion of the cover with an interposition of the gasket.

The present invention increases a projecting height in the compression direction of the gasket in the small width portion according to the raising to improve sealability based on the gasket.

### BRIEF DESCRIPTION OF THE DRAWINGS

FIG. 1 is a plan view of a recording device according to an embodiment 1 of the present invention;

FIG. 2A is a schematic sectional view according to a line II-II of the recording device of FIG. 1, and FIG. 2B is a schematic sectional view according to a modified embodiment;

FIG. 3A and FIG. 3B are schematic sectional views illustrating part of FIG. 2A with enlargement;

FIG. 4 is a bottom view of a cover of the recording device of FIG. 1;

FIG. 5A is a bottom view of the cover illustrating a small width portion and its periphery of a gasket provided on the cover of FIG. 4, and FIG. 5B is a sectional view according to a line V-V of FIG. 5A;

FIG. 6A is a sectional view according to a line VIA-VIA of FIG. 5A, and FIG. 6B is a sectional view according to a line VIB-VIB of FIG. 5A;

FIG. 7 is a graph illustrating an example of a correlation between a width and a projection height of the gasket in a single layer;

FIG. 8A is a sectional view illustrating a small width portion and its periphery of a gasket according to an embodiment 2 of the present invention, and FIG. 8B is a sectional view according to a line VIII-VIII of FIG. 8A;

FIG. 9 is a sectional view illustrating a small width portion and its periphery of a gasket according to an embodiment 3 of the present invention;

FIG. 10A is a bottom view of a cover illustrating a small width portion and its periphery of a gasket according to an embodiment 4 of the present invention, and FIG. 10B is a sectional view according to a line X-X of FIG. 10 A; and

FIG. 11 is a sectional view of a gasket according to a modified embodiment of the embodiment 4.

### EMBODIMENT FOR CARRYING OUT THE INVENTION

The object improving sealability of a gasket having a small width portion is accomplished by raising the small width portion.

As illustrated in drawings, a cover 19 is to be attached to an opening 17a of a base 17 of a housing 3 accommodating an internal mechanism 5 in a space 3a to close the space 3a. The cover 19 is provided with an outer peripheral portion 19a received by the base 17, and a gasket 29 extending along the outer peripheral portion 19a in a circumferential shape and projecting from the outer peripheral portion 19a to be compressed by contact to the base 17. The gasket 29 is provided with a large width portion 31 being relatively large in width spanning between an inside and an outside of the circumferential shape and a small width portion 33 being relatively small in the width. The small width portion 33 is raised by a layer structure having a raising layer 35 or 37 in a compression direction of the gasket 29.

The small width portion 33 may be provided with a first layer 35 as the raising layer and a second layer 37 stacked on the first layer 35, and the large width portion 31 may be formed integrally with the second layer 37 of the small width portion 33. In this case, it may be configured that a transition portion 39 is provided between the second layer 37 of the small width portion 33 and the large width portion 31, and is gradually reduced from the large width portion 31 toward the small width portion 33 in height in the compression direction and width of the gasket 29.

It may be configured that an end portion 35a of the first layer 35 of the small width portion 33 in an extending direction of the gasket 29 is located in the transition portion 39, and is gradually increased in height in the compression direction and width as is apart from the large width portion 31 in the extending direction.

The large width portion 31 may be a single layer or a multilayer. If the large width portion is a multilayer, the large width portion may be provided with a first layer 41 and a second layer 43 integrated with the first layer 35 and the second layer 37 of the small width portion 33, respectively. In this case, it may be configured that the second layer 43 of the large width portion 31 envelopes the first layer 41 of the large with portion 31.

In the small width portion 33, the second layer 37 may be the raising layer. In this case, the first layer 35 is formed integrally with the large width portion 31 and the second layer 37 is stacked on the first layer. A transition portion may be provided between the first layer 35 of the small width portion 33 and the large width portion 31. An end portion 37a of the second layer 37 of the small width portion 33 in an extending direction of the gasket 29 may be located on the transition portion 39, and may be gradually increased in height in the compression direction and width as is apart from the large width portion 31 in the extending direction.

The small width portion 33 and the large width portion 31 may be eccentric in a width direction. Further, the first layer 35 and the second layer 37 of the small width portion 33 may be eccentric in the width direction.

A recording device 1 using the aforementioned cover 19 is provided with the base 17 forming the housing 3 together with the cover 19 to accommodate the internal mechanism 5 in the closed space 3a. The base 17 is provided with the opening 17a to which the cover 19 is attached, and a cover-receiving portion 25 receiving the outer peripheral portion 19a of the cover 19 with an interposition of the gasket 29.

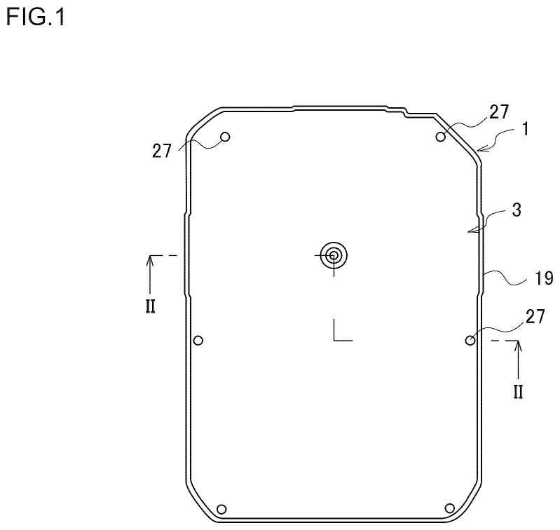

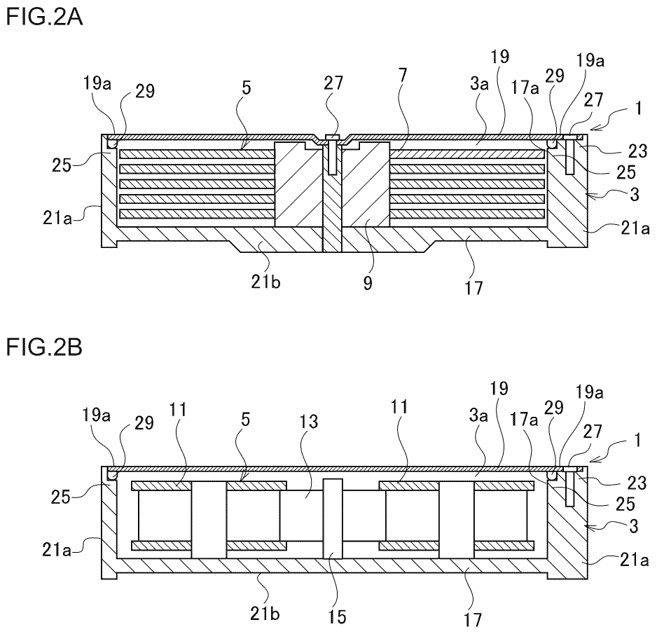

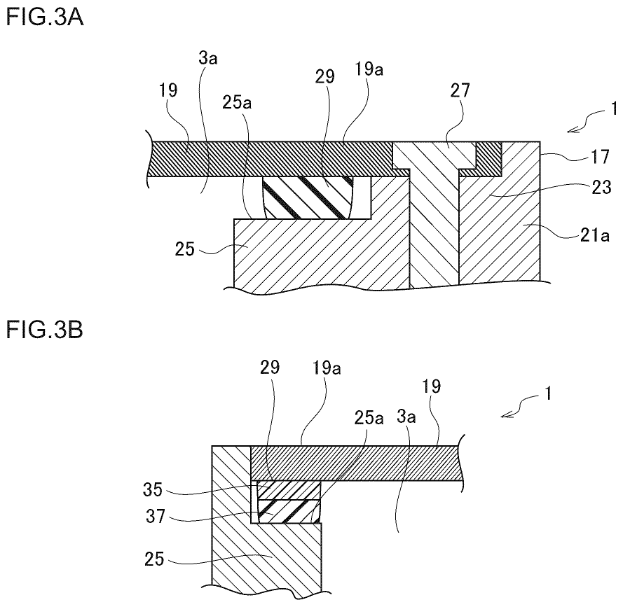

FIG. 1 is a plan view of a recording device according to the embodiment 1 of the present invention. FIG. 2A is a schematic sectional view according to a line II-II of the recording device of FIG. 1, and FIG. 2B is a schematic sectional view according to the modified embodiment. FIG. 3A and FIG. 3B are schematic sectional views illustrating parts of FIG. 2A of a gasket and its periphery on both sides with enlargement.

A recording device 1 of the present embodiment is a hard disk drive as a magnetic disk device, and accommodates an internal mechanism 5 in a space 3a within a housing 3.

The internal mechanism 5 is provided with a spindle motor 9 and the like in addition to disks 7 being recording media. The disks 7 are stacked in a plural in a thickness direction of the recording device 1 (hereinafter, referred to simply as “thickness direction”), and are rotatably supported by the spindle motor 9. The disks 7 are configured so that information is written and read through heads not illustrated.

It should be noted that the recording device 1 is not limited to the magnetic disk device and may be another disk device such as optical disk device or another recording device other than the disk device. For example, the recording device 1 may be a tape-embedded type drive as illustrated in FIG. 2B. This recording device 1 accommodates a tape film 13 as a recoding medium wound between two tape reels 11 and a head assembly 15 to read and write information in the space 3a of the housing 3 as the internal mechanism 5.

The housing 3 is composed of a base 17, and a cover 19 to be closed or sealed inside.

The base 17 is made of metal such as aluminum, and is formed into a box shape having an opening 17a on one side in the thickness direction. It should be noted that the base 17 is sufficient to be a box shape capable of accommodating the internal mechanism 5 including the disks 7, and may have an appropriate shape in this context. The base 17 of the present invention is formed into an approximate rectangular shape in a plan view, for example. In addition, the plan view means a state seen in the thickness direction and does not mean to distinguish a plan and a bottom.

The base 17 is closed by the cover 19 attached to the opening 17a on the one side in the thickness direction. This seals the space 3a in the housing 3 accommodating the internal mechanism 5. The sealed space 3a may seal gas such as helium with lower resistance than air.

A side wall portion 21a is provided circumferentially on an outer peripheral portion of the base 17 so that the opening 17a is defined by the side wall portion 21a. In addition, the outer peripheral portion of the base 17 is an outer peripheral region surrounding the internal mechanism 5, and is a portion on which the side wall portion 21a is provided in the present embodiment.

The side wall portion 21a is raised integrally from a bottom wall portion 21b of the base 17, the bottom wall portion formed into a plate shape. The side wall portion 21a may be formed separately from the bottom wall portion 21b of the base 17 and be connected to the bottom wall portion to be integrally.

The side wall portion 21a is provided with fastening portions 23 and a cover receiving portion 25.

The fastening portions 23 of the base 17 are portions at which the cover 19 is fastened relative to the base 17. In the present embodiment, the fastening portions 23 are provided at a plurality of positions, for example, 6 positions so as to be spaced in a circumferential direction of the base 17. It should be noted that the fastening portion 23 may be circumferentially formed along the outer peripheral portion of the base 17. The circumferential direction of the base 17 means a circumferential direction along the side wall portion 21a of the base 17.

The fastening portions 23 are in contact with the cover 19 to receive the cover in the thickness direction. In this contact state, the cover 19 is fastened to the fastening portions 23 using fastening tools, for example, bolts 27. In addition, the cover 19 is also fastened to the spindle motor 9 using the bolt 27. As the fastening tools, rivets or the like may be used instead of the bolts 27.

The cover-receiving portion 25 receives the outer peripheral portion 19a of the cover 19 with interposition of the gasket 29 attached to the cover 19. With this, the gasket 29 is compressed between the cover-receiving portion 25 and the cover 19 in the thickness direction.

The cover-receiving portion 25 of the present embodiment is provided circumferentially along the side wall portion 21a of the base 17 in the plan view. The cover-receiving portion 25 may be, however, partially provided on the outer peripheral portion of the base 17.

The cover-receiving portion 25 has a receiving face 25a formed flat along a width direction. The outer peripheral portion 19a of the cover 19 is received by the receiving face 25a with which the gasket 29 is brought into contact. It should be noted that the receiving face 25a may not be flat and may have irregularities or the like as long as the gasket 29 is brought into contact with the receiving face.

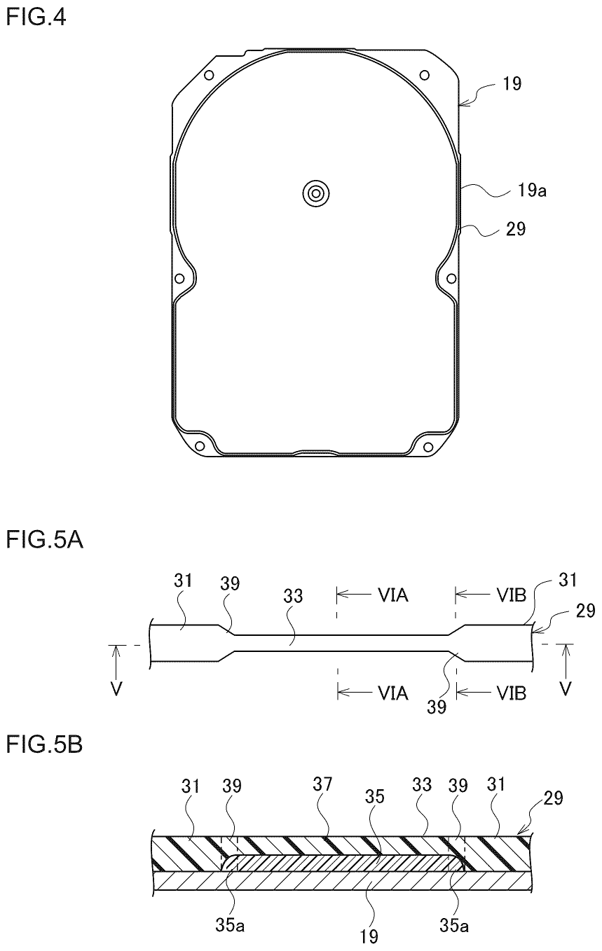

FIG. 4 is a bottom view of the cover of the recording device of FIG. 1.

As illustrated in FIGS. 1-4, the cover 19 is formed of a plate material made of metal such as aluminum. The cover 19 is formed entirely into flat plate shape covering the opening 17a of the base 17. The cover 19 of the present embodiment is formed into an approximate rectangular shape in the plan view corresponding to the base 17. A form such as shape of the cover 19, however, is not limited particularly as long as the cover covers the opening 17a of the base 17. Further, the material of the cover 19 is optional.

The cover 19 is received by the base 17 at the outer peripheral portion 19a in a state of covering the opening 17a of the base 17. In particular, the outer peripheral portion 19a of the cover 19 is received by the cover-receiving portion 25 of the base 17 in the thickness direction. In addition, the outer peripheral portion 19a is a circumferential portion received by the base 17. To the outer peripheral portion 19a of the cover 19, the gasket 29 for sealing is attached.

The gasket 29 is extended circumferentially along the outer peripheral portion 19a of the cover 19. The gasket 29 is projected from the outer peripheral portion 19a in the thickness direction and is compressed by contact with the base 17. In particular, the gasket 29 projected form the outer peripheral portion 19a of the cover 19 is in contact with the cover-receiving portion 25 of the base 17, and is compressed and interposed between the base 17 and the cover 19 according to fixing of the cover 19 to the base 17.

It should be noted that, although a projection direction and a compression direction of the gasket 29 are identical with the thickness direction according to the present embodiment, the projection direction and the compression direction may be different. Further, although the projection direction and the compression direction are preferably identical with each other, the projection direction and the compression direction may be different from each other as long as the gasket 29 is projected with respect to the cover 19 in the compression direction and is compressed to ensure sealability. Hereinafter, the present embodiment provide the explanation while regarding the projection direction and the compression direction as the thickness direction.

The compressed gasket 29 seals between the cover 19 and the base 17. The gasket 29 of the present embodiment is compressed between the cover 19 and the cover-receiving portion 25 of the base 17 to seal between the cover 19 and the cover-receiving portion 25.

For the gasket 29 of the present embodiment, a liquid gasket such as FIPG (Formed In Place Gasket) is used. Namely, the gasket 29 is discharged from an application tool such as needle and is applied onto the outer peripheral portion 19a of the cover 19 in advance, and is cured to be fixed.

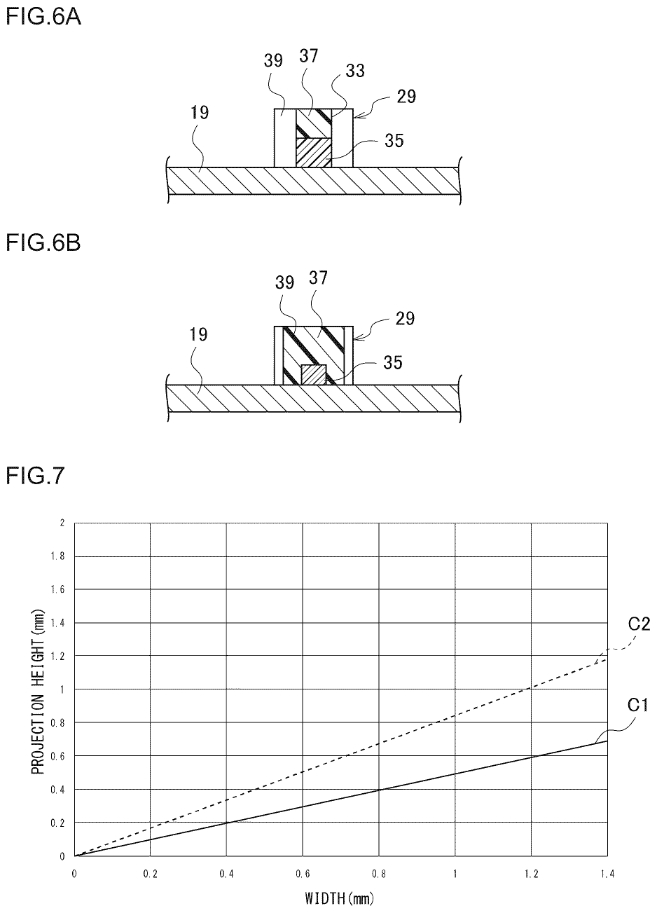

FIG. 5A is a bottom view of the cover 19 illustrating a small width portion and its periphery of the gasket provided on the cover 19 of FIG. 4, and FIG. 5B is a sectional view according to a line V-V of FIG. 5A. FIG. 6A is a sectional view according to a line VIA-VIA of FIG. 5A, and FIG. 6B is a sectional view according to a line VIB-VIB of FIG. 5A.

In addition, FIG. 5B indicates a cross-section along an extending direction of the gasket 19 and the thickness direction, FIGS. 6A and 6B indicate cross-sections orthogonal to the extending direction of the gasket 19. Further, FIG. 6A and B indicate relation among a first layer 35, a second layer 37, and a transition portion 39 of the small width portion 33, and use the conceptually squared cross-section of the small width portion 33.

The gasket 29 of the present embodiment is provided with large width portions 31 and the small width portion 33.

The large width portion 31 is a portion being relatively large in width spanning between an inside and an outside of the circumferential shape of the gasket 29 and the small width portion 33 is a portion being relatively small in the width spanning between the inside and the outside of the circumferential shape of the gasket 29. The adjacent large width portions 31 and small width portion 33 are concentrically arranged in the width direction. The concentricity is that widthwise centers of the large width portions 31 and the small width portion 33 are concentric in the width direction.

It should be noted that, although the widths of the small width portion 33 and the large width portion 31 are largest widths (maximum widths) in the small width portion 33 and the large width portion 31, respectively, the widths may be smallest widths (minimum widths), averages of the widths or the like. In the large width portion 31 and the small width portion 33, although the respective widths are constant, the widths may be varied in the extending direction.

The small width portion 33 is a portion of the gasket 29 in the extending direction, the portion reduced in width according to spatial restriction for avoiding interference to the internal mechanism 5 or the like. It should be noted that one or more small width portions 33 are provided in the extending direction.

The small width portion 33 is raised by a layer structure having a raising layer in the thickness direction as the compression direction of the gasket 29. The raising means that the small width portion 33 is raised in the thickness direction relative to a case of the small width portion having number of layers being the same as of the large width portion 31. The number of layers means number of layers stacked one layer on another layer and number of layers enveloped is excluded. The enveloping is a state that another layer is embedded in one layer although a layer structure is multilayer, and forms a single layer according to the one layer in viewpoint of the number of layers. The small width portion 33 including the raising layer, therefore, has the number of layers more than of the large width portion 31.

With this configuration, a projection height is suppressed from varying between the small width portion 33 and the large width portion 31 in the thickness direction in a free state of the gasket 29. This improves the sealability of the gasket 29. It should be noted that the projection height is a height in the thickness direction being the projection direction of the gasket 29 from the cover 19.

The projection height of the gasket 29 of the present embodiment is even between the small width portion 33 and the large width portion 31 in the free state. The projection height of the gasket 29 at the small width portion 33, however, may be larger or smaller than at the large width portion 31. In addition, the free state is an unloaded state in which no compression load acts on the gasket 29 and is an unclosed state before the opening 17a of the base 17 is closed by the cover 19 in the present embodiment.

In the present embodiment, the large width portion 31 is a single layer and the small width portion 33 is multilayer, in particular two-layer. The number of layers of the large width portion 31 and the small width portion is, however, optionally set as long as the small width portion 33 is raised. It should be noted that the single layer of the large width portion 31 means a single layer in a layer structure and number of layers in contrast to the enveloping. Hereinafter, simply stating the single layer means the single layer in the layer structure and number of layers.

The single-layer large width portion 31 is set in width and height in the thickness direction when a liquid gasket is discharged from a needle. It should be noted that, when simply stating the height, the height is a dimension in the thickness direction being the compression direction unlike the projection height from the cover 19 (the same applies to the following). The width and the height in the case of curing the liquid gasket discharged from the needle have correlation in which only any one of the width and the height is not increased or reduced in a single layer. According to this correlation, the large width portion 31 is set in width and height.

FIG. 7 illustrates an example of a correlation between the width and the height of the gasket in the single layer. In the example of FIG. 7, different correlations C1 and C2 in width and height are obtained by varying discharging conditions, for example, a discharging amount of the liquid gasket, moving speed of the needle, a distance between an application face of the cover 19 and the application tool and the like. Within a range between the correlations C1 and C2, the width (and the height) of the large width portion 31 is adjusted. In addition, the moving speed of the needle is moving speed in the extending direction.

The two-layer small width portion 33 is provided with the first layer 35 and the second layer 37.

The first layer 35 is a layer contacting the cover 19 in the small width portion 33, and has a function as the raising layer. The second layer 37 is a layer stacked on the first layer 35 in the thickness direction. The second layer 37 is arranged concentrically with the first layer 35 in the width direction.

The first layer 35 and the second layer 37 are made of same material liquid gaskets. It should be noted that the first layer 35 and the second layer 37 may be different material liquid gaskets. Each of the first layer 35 and the second layer 37 is set in width and height when the liquid gasket is discharged from the needle to be applied to the cover 19 similarly to the large width portion 31.

In the application of the first layer 35 and the second layer 37, the second layer 37 is applied together with the large width portion 31 after the application of the first layer 35. If a plurality of the small width portions 33 are present, the application of the first layer 35 is performed at each of positions corresponding to the small width portions 33. The application of the second layer 37 is performed together with the application of the large width portion 31 while changing the discharging conditions at the position corresponding to the small width portion 33. Thereafter, the gasket 29 is entirely cured. It should be noted that the first layer 35 may be applied and thereafter cured and the large width portion 31 and the second layer 37 may be applied and thereafter cured in additional.

In this way, the second layer 37 is formed integrally with the large width portion 31, and have the constant width and height. The second layer 37 is formed integrally with the large width portion 31, thereby suppressing variation in projection height of the gasket 29 to improve sealability. Further, the transition portions 39 are provided between the large width portions 31 and the second layer 37 of the small width portion 31, and the transition portions 39 smoothly transition between the large width portions 31 and the second layer 37 of the small width portion 33, thereby suppressing the variation of the projection height of the gasket 29 to improve the sealability. In addition, the transition portions 39 may be omitted.

The transition portion 39 is gradually reduced in width and height from the large width portion 31 to the small width portion 33. The gradually reducing in width and height is reduction continuous or stepwise in width and height. The transition portion 39 of the present embodiment is continuously reduced in width with an inclined linear shape on each side in the width direction and is continuously reduced in height with a parabolic shape. A shape of the transition portion may be optionally set.

For example, both the width and the height of the transition portion 39 may be reduced with parabolic shapes or linear shape. Further, one gradually reducing in width and height may be a shape in which portions continuously reducing in width and height are connected by portions with fixed widths and heights or a shape in which portions with fixed different widths and heights are connected.

End portions 35a of the first layer 35 in the extending direction are positioned in the transition portions 39. The end portion 35a is gradually increased in width and height as is apart from the large width portion 31 in the extending direction contrary to the transition portion 39. This enables to suppress variation of the projection height of the gasket 29 in cooperation with the transition portion 39.

The gradually increasing in width and height is increased continuously or stepwise in width and height. Although the width and the height are continuously increased with a parabolic shape in the present embodiment, the width and the height may be continuously linearly increased. Further, one gradually increasing in width and height may be a shape in which portions continuously increasing in width and height are connected by portions with fixed widths and heights or a shape in which portions with fixed different widths and heights are connected.

The width and the height of the first layer 35 excluding the end portions 35a are the same as of the second layer 37 and constant. With this, edges of the first layer 35 correspond to edges of the second layer 37 in the width direction. It should be noted that the width and the height of the first layer 35 excluding the end portions 35a do not need to be the same as of the second layer 37 and may be larger or smaller than of the second layer 37.

In any cases, a difference between the small width portion 33 and the large width portion 31 in the projection height is smaller than a case without the raising according to the first layer 35. This is because it is preferable that variation in height is suppressed between the small width portion 33 and the large width portion 31 in order to ensure the sealability of the gasket 29.

In manufacturing of the recording device 1 of the present embodiment, the cover 19 is attached to the base 17 of the housing 3 accommodating the disks 7, to close the space 3a of the housing 3 accommodating the disks 7.

Namely, the cover 19 to which the gasket 29 is attached is faced to the opening 17a of the base 17 in the thickness direction. In this state, the cover 19 and the base 17 are closer to each other to bring a tip end portion of the gasket 29 into contact with the cover-receiving portion 25 of the base 17.

The cover 19 and the base 17 are further closer to each other so that the gasket 29 is compressed between the cover 19 and the base 17. At this time, since the gasket 29 of the present embodiment is increased in projection height of the small width portion 33 according to the raising, the gasket is sufficiently compressed at the small width portion 33 as well as the large width portion 31. The gasket 29, therefore, improves in sealability as a whole.

Further, the second layer 37 being a top layer of the small width portion 33 and the large width portion 31 are integrated in the present embodiment, so that the tip end portion of the gasket 29 is smooth between the small width portion 33 and the large width portion 31. The gasket 29, therefore, improves the sealability.

Furthermore, the transition portion 39 between the second layer 37 of the small width portion 33 and the large width portion 31 is gradually reduced in width and height toward the small width portion 33 in the present embodiment. On the other hand, the end portion 35a of the first layer 35 of the small width portion 33 is located in the transition portion 39, and is gradually increased in width and height as is apart from the large width portion 31 in the extending direction. Accordingly, variation in projection height of the gasket 29 is more certainly suppressed to improve the sealability.

Thereafter, the cover 19 is fastened to the base 17 using the bolts 27, to close the space 3a of the housing 3 accommodating the disks 7.

### Embodiment 2

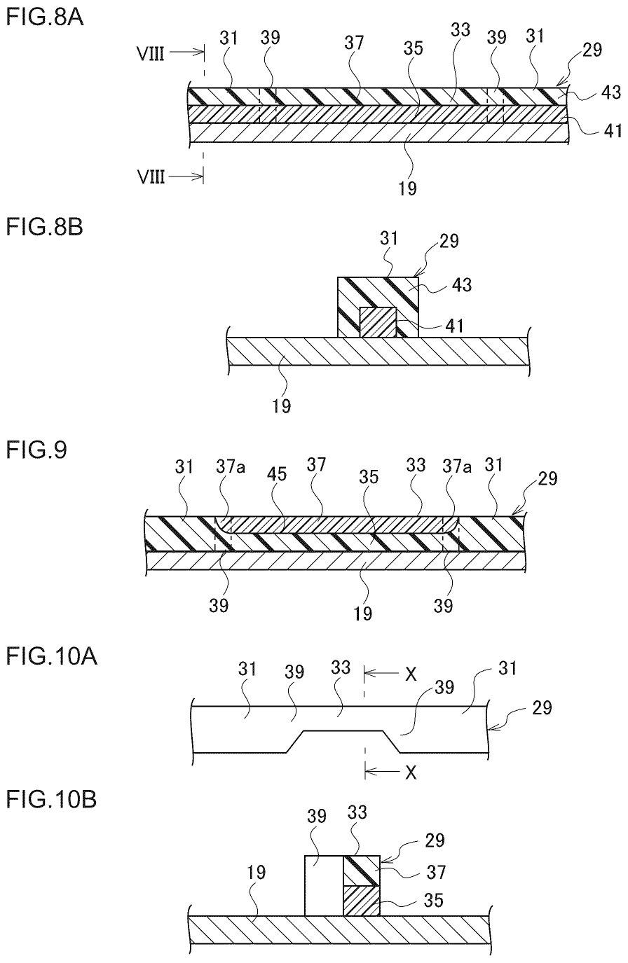

FIG. 8A is a sectional view illustrating a small width portion and its periphery of a gasket according to the embodiment 2 of the present invention, and FIG. 8B is a sectional view according to a line VIII-VIII of FIG. 8A. In addition, in the embodiment 2, the basic structure is in common with the embodiment 1 and therefore corresponding components are represented with the same reference numerals to eliminate duplicate explanation. FIG. 8A is a cross-section along an extending direction of the gasket. Further, FIG. 8B indicates a schematic square cross-section of a large width portion 31.

The present embodiment makes a large width portion 31 of the gasket 29 multilayer. Namely, the large width portion 31 is provided with a first layer 41 and a second layer 43.

The first layer 41 of the large width portion 31 are configured so as to be integrally continuous to a first layer 35 of a small width portion 33 and has the same width and the same height as of the first layer 35 of the small width portion 33. It should be noted that the width and the height of the first layer 41 of the large width portion 31 do not need to be the same as of the small width portion 33.

The second layer 43 of the large width portion 31 has the same width and the same height as of the large width portion 31 of the embodiment 1 and envelopes the first layer 41. The second layer 43 of the large width portion 31, therefore, is in a state that the first layer 41 is embedded into the second layer and is a single layer in viewpoint of number of layers.

The second layer 43 of the large width portion 31 is configured integrally with the second layer 37 of the small width portion 33, and is continuous to the second layer 37 of the small width portion 33 through a transition portion 39. The transition portion 39 is gradually reduced in width and height toward the small width portion 33 similar to the embodiment 1. Others are the same as of the embodiment 1.

The embodiment 2 having the structure provides the same effects as the embodiment 1 and easily forms the gasket 29 because of continuously circumferentially forming the first layers 41 and 35 of the large width portion 31 and the small width portion 33 together.

FIG. 9 is a sectional view illustrating a small width portion and its periphery of a gasket according to the embodiment 3 of the present invention. In addition, in the embodiment 3, the basic structure is in common with the embodiment 1 and therefore corresponding components are represented with the same reference numerals to eliminate duplicate explanation. FIG. 9 is a cross-section along an extending direction of the gasket.

The present embodiment makes a second layer 37 of the small width portion 33 be a raising layer.

Namely, a first layer 35 of the small width portion 33 is formed integrally with a single-layer large width portion 31. The first layer 35 is continuous to the large width portion 31 through a transition portion 39. The large width portion 31 has the same width and the same height as the embodiment 1. The transition portion 39 is gradually reduced in width and height toward the small width portion 33 and the first layer 35 of the small width portion 33 has the same width and the same height as the first layer 35 of the embodiment 1. This forms a recessed portion 45 from the transition portions 39 over the first layer 35 of the small width portion 33.

Within the recessed portion 45, the second layer 37 of the small width portion 33 is positioned. In the present embodiment, the recessed portion 45 and the second layer 37 have the same sectional shape. The second layer 37 has the same width and the same height as the second layer 37 of the embodiment 1 on the first layer 35, and end portions 37a of which gradually increasing in width and height are positioned on the transition portions 39.

It should be noted that the sectional shape of the second layer 37 may be larger or smaller than the recessed portion 45. If the sectional shape of the second layer 37 is larger than the recessed portion 45, the second layer 37 is projected from the large width portion 31 in the thickness direction. If the sectional shape of the second layer 37 is smaller than the recessed portion 45, the second layer 37 is recessed with respect to the large width portion 31 in the thickness direction.

Others are the same as of the first embodiment.

Even the embodiment 3 having that structure provides the same effects as the embodiment 1.

FIG. 10A is a bottom view of a cover illustrating a small width portion and its periphery of a gasket according to the embodiment 4 of the present invention, and FIG. 10B is a sectional view according to a line X-X of FIG. 10A. In addition, in the embodiment 4, the basic structure is in common with the embodiment 1 and therefore corresponding components are represented with the same reference numerals to eliminate duplicate explanation. FIG. 10B indicates a schematic square cross-section of a small width portion 33.

The present embodiment makes the small width portion 33 widthwise eccentric with respect to a large width portion 31. In response to this, a shape of a transition portion 39 is altered relatively to the embodiment 1. The eccentricity is a deviation between a widthwise center of the small width portion 33 and a widthwise center of the large width portion 31 in a width direction in a cross-section orthogonal to an extending direction of a gasket 29.

An outer edge portion of the small width portion 33 corresponds to an outer edge portion of the large width portion 31 in the width direction according to the eccentricity. It should be noted that the amount of the eccentricity may be appropriately set and there is no need to correspond the outer edge portion of the small width portion 33 to the outer edge portion of the large width portion 31. The transition portion 39 is gradually reduced in width only on an inner edge portion in the width direction. Others are the same as of the embodiment 1.

Even the embodiment 4 having that structure provides the same effects as the embodiment 1. Further, the gasket 29 is suppressed from projecting or swelling inward in the width direction at the time of compressing according to the eccentricity between the small width portion 33 and the large width portion 31.

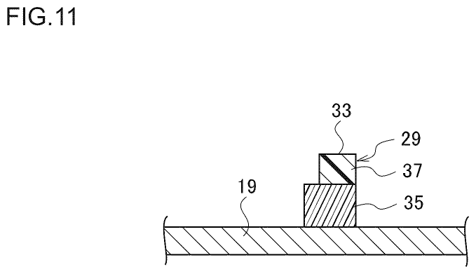

FIG. 11 is a sectional view of the small width portion 33 of the gasket 29 according to a modified embodiment of the embodiment 4 and indicates a schematic square cross-section of the small width portion 33.

The modified embodiment of FIG. 11 makes the first layer 35 and the second layer 37 of the small width portion 33 eccentric in the width direction. Namely, the second layer 37 is smaller than the first layer 35 in width and height, and is eccentric widthwise outward with respect to the first layer 35. According to the eccentricity, the outer edge portion of the first layer 35 and the outer edge portion of the second layer 37 correspond to each other in the width direction.

It should be noted that the eccentricity is a deviation between a widthwise center of the first layer 35 of the small width portion 33 and a widthwise center of the second layer 37 of the small width portion 33 in a width direction in a cross-section orthogonal to the extending direction of the gasket 29. The amount of the eccentricity may be appropriately set and there is no need to correspond the outer edge portion of the first layer 35 to the outer edge portion of the second layer 37. The modified embodiment of FIG. 11 may be applied to the small width portion 33 of any one of the embodiments 1-4.

In the modified embodiment, the gasket 29 is suppressed from projecting or swelling inward in the width direction at the time of compressing according to the eccentricity between the first layer 35 and the second layer 37.

1. A cover to be attached to an opening of a base of a housing accommodating an internal mechanism in a space to close the space, comprising:
an outer peripheral portion received by the base; and
a gasket extending along the outer peripheral portion in a circumferential shape and projecting from the outer peripheral portion to be compressed by contact to the base, wherein
the gasket has a large width portion being relatively large in width spanning between an inside and an outside of the circumferential shape and a small width portion being relatively small in the width, and
the small width portion is raised by a layer structure having a raising layer in a compression direction of the gasket.

2. The cover according to claim 1, wherein
the small width portion is provided with a first layer as the raising layer and a second layer stacked on the first layer,
the large width portion is formed integrally with the second layer of the small width portion, and
a transition portion is provided between the second layer of the small width portion and the large width portion, and is gradually reduced from the large width portion toward the small width portion in height in the compression direction and width.

3. The cover according to claim 2, wherein
an end portion of the first layer of the small width portion in an extending direction of the gasket is located in the transition portion, and is gradually increased in height in the compression direction and width as is apart from the large width portion in the extending direction.

4. The cover according to claim 2, wherein
the large width portion is provided with a first layer and a second layer integrated with the first layer and the second layer of the small width portion, respectively, and
the second layer of the large width portion envelopes the first layer of the large with portion.

5. The cover according to claim 1, wherein
the large width portion is a single layer.

6. The cover according to claim 1, wherein
the small width portion is provided with a first layer and a second layer as the raising layer stacked on the first layer,
the large width portion is formed integrally with the first layer of the small width portion, and
a transition portion is provided between the first layer of the small width portion and the large width portion, and is gradually reduced from the large width portion toward the small width portion in height in the compression direction and width.

7. The cover according to claim 6, wherein
an end portion of the second layer of the small width portion in an extending direction of the gasket is located on the transition portion, and is gradually increased in height in the compression direction and width as is apart from the large width portion in the extending direction.

8. The cover according to claim 1, wherein
the small width portion and the large width portion are eccentric in a width direction.

9. The cover according to claim 1, wherein
the first layer and the second layer of the small width portion are eccentric in a width direction.

10. A recording device using the cover according to claim 1, comprising;
a base forming a housing together with the cover to accommodate an internal mechanism in a closed space, wherein
the base is provided with an opening to which the cover is attached, and a cover-receiving portion receiving the outer peripheral portion of the cover with an interposition of the gasket.
